(19) United States
(12) Patent Application Publication
(10) Pub. No.: US 2020/0274071 A1
(43) Pub. Date: Aug. 27, 2020

(54) Composition for Organic Electroluminescent Device, Hole Injection Layer Material Manufactured Therefrom, and Organic Electroluminescent Device Comprising Hole Injection Layer

(71) Applicant: Korea University Research and Business Foundation, Sejong Campus, Sejong-si (KR)

(72) Inventors: Seung Yoon Ryu, Hwaseong-Si (KR); Donghyun Kim, Sejong-si (KR); Chang Min Lee, Busan (KR); Hafeez Hassan, Sejong-si (KR)

(21) Appl. No.: 16/755,649

(22) PCT Filed: Feb. 14, 2019
(86) PCT No.: PCT/KR2019/001805

§ 371 Date: Apr. 13, 2020

(30) Foreign Application Priority Data
Feb. 21, 2018 (KR) 10-2018-0020531
Feb. 13, 2019 (KR) 10-2019-0016567

(51) Int. Cl. H01L 51/00

(52) U.S. Cl. CPC H01L 51/0071; H01L 51/5056; H01L 51/0034

(57) ABSTRACT

The present invention relates to a composition for an organic electroluminescent device, a hole injection layer material manufactured therefrom, and an organic electroluminescent device comprising the hole injection layer. Specifically, the organic electroluminescent device employing the hole injection layer material produced by using a composition for an organic electroluminescent device according to the present invention can realize remarkably improved efficiency and effectively suppress the problem of shortening the lifespan of the device due to high acidity.

### TECHNICAL FIELD

The present invention relates to a composition for an organic electroluminescent device, a hole injection layer material produced therefrom, and an organic electroluminescent device including a hole injection layer.

### BACKGROUND ART

An organic electroluminescent device refers to an active light emitting display device that emits light by a combination of electrons and holes in a fluorescent or phosphorescent organic compound thin layer (hereinafter, referred to as an “organic layer”) when a current is applied thereto. Since the organic electroluminescent device may be driven at a low voltage, has a relatively low power consumption, and may perfectly implement a high color purity, the organic electroluminescent device has been expected to a next generation display device.

In general, an organic electroluminescent device has a structure in which an anode is formed on a substrate, and a hole transfer layer, a hole transport layer, a light emitting layer, an electron transport layer, and a cathode are sequentially stacked on the anode. The hole transfer layer, the hole transport layer, the light emitting layer, and the electron transport layer are organic layers formed of an organic compound or an organic/inorganic mixed compound.

A driving principle of the organic electroluminescent device having the structure as described above operates as follows. When a voltage is applied to the anode and the cathode, holes injected from the anode migrate to the light emitting layer via the hole transport layer. Meanwhile, electrons are injected from the cathode to the light emitting layer via the electron transport layer. Carriers are recombined in the light emitting layer, and thus excitons are formed. Light with a wavelength corresponding to a band gap of a material is emitted when the excitons radiatively decay.

In order to implement an improved efficiency of the organic electroluminescent device based on such a driving principle, materials for forming an organic layer, such as a material for a hole transfer layer, a material for a hole transport layer, a material for a light emitting layer, and a material for an electron transport layer, are required to be stable and have an efficient charge balance. However, a material for forming an organic layer for an organic electroluminescent device that is stable and has an efficient charge balance has not yet been sufficiently developed.

Therefore, for the organic electroluminescent device expected to be a next generation display device, the development of a new material having an excellent light emitting property and lifespan has been constantly required.

### DISCLOSURE

### Technical Problem

An object of the present invention is to provide a composition for an organic electroluminescent device, a hole injection layer material produced therefrom, and an organic electroluminescent device including a hole injection layer that implement an improved light emitting property and lifespan.

### Technical Solution

In one general aspect, there is provided a composition for an organic electroluminescent device, the composition containing: a conductive polymer composite having an acidic group; and a compound of the following Formula 1.

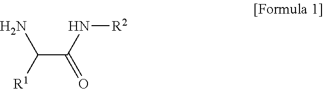

[In Formula 1,

R¹ is C₃-C₃₀cycloalkyl, C₃-C₃₀heterocycloalkyl, C₆-C₃₀aryl, or C₆-C₃₀heteroaryl;

R² is a lactam group or a fused lactam group;

the cycloalkyl, the heterocycloalkyl, the aryl, or the heteroaryl of R¹, and the lactam group or the fused lactam group of R² each independently may be further substituted with one or more substituents selected from halogen, hydroxy, cyano, carboxyl, carboxylate, C₁-C₃₀alkyl, C₁-C₃₀alkoxy, C₂-C₃₀alkenyl, C₂-C₃₀alkynyl, C₆-C₃₀aryl, and C₆-C₃₀heteroaryl; and

the heterocycloalkyl or the heteroaryl of R¹, and the lactam group or the fused lactam group of R² each independently include one or more selected from B, N, O, S, Se, —P(═O)—, —C(═O)—, Si, and P.]

In the compound of Formula 1, R¹ may be C₃-C₃₀cycloalkyl or C₆-C₃₀aryl; and R² may be a lactam group fused with an alicyclic ring.

In the compound of Formula 1, R¹ may be C₃-C₃₀cycloalkyl or C₆-C₃₀aryl; and R² may be represented by the following Formula 2.

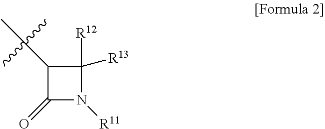

[In Formula 2,

R¹¹ is C₁-C₇alkyl or C₂-C₇alkenyl;

one of R¹² and R¹³ is hydrogen, C₁-C₇alkyl, C₁-C₇alkoxy, or C₁-C₇thioxy, and the other one may be connected to R¹¹ to form an alicyclic ring; and

the alkyl or the alkenyl of R¹¹ and the alicyclic ring formed by connecting one of R¹² and R¹³ to R¹¹ each independently may be further substituted with one or more substituents selected from halogen, hydroxy, cyano, carboxyl, carboxylate, C₁-C₇alkyl, C₁-C₇alkoxy, C₂-C₇alkenyl, C₂-C₇alkynyl, C₆-C₁₂aryl, and C₆-C₁₂heteroaryl, and —CH₂— in the alicyclic ring may be substituted with a heteroatom selected from O and S.]

Specifically, the compound may be at least one selected from a compound of the following Formula 3 and a compound of the following Formula 4.

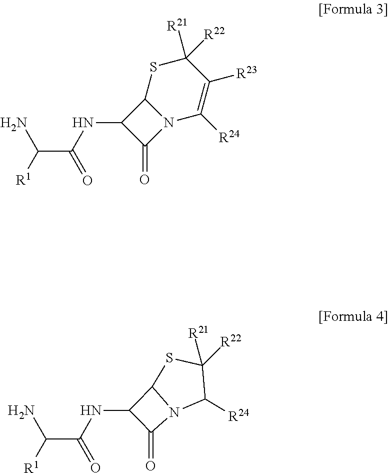

[In Formulas 3 and 4,

R¹ is C₃-C₁₂cycloalkyl or C₆-C₁₂aryl;

R²¹ to R²⁴ are each independently selected from hydrogen, halogen, hydroxy, cyano, carboxyl, carboxylate, and C₁-C₇alkyl; and

the cycloalkyl or the aryl of R¹ each independently may be further substituted with one or more substituents selected from halogen, hydroxy, cyano, carboxyl, and C₁-C₇alkyl.]

More specifically, the compound may be one or two or more selected from ampicillin, amoxicillin, cephalexin, cefradine, and cefaclor.

The conductive polymer composite having an acidic group may be a mixture of a polythiophene-based polymer and an aromatic sulfonate-based polymer.

The conductive polymer composite having an acidic group may be a mixture of poly(3,4-ethlenedioxythiophene) and poly(styrenesulfonate).

A pH of the composition may be 9.0 or less.

A pH of the composition may be 2.0 to 8.5.

The composition may contain a primary amine group in the compound of Formula 1 in an amount of 10 moles or less, based on 1 mole of a sulfonic acid ion of the poly(styrenesulfonate).

In another general aspect, there is provided a hole injection layer material produced by using the composition for an organic electroluminescent device, the composition containing: a conductive polymer composite having an acidic group; and a compound of Formula 1.

In still another general aspect, there is provided an organic electroluminescent device containing the hole injection layer material.

The organic electroluminescent device may include an anode, a hole injection layer containing the hole injection layer material, a hole transport layer, a light emitting layer, an electron transport layer, and a cathode.

The organic electroluminescent device may be a display device, or a device for monochromatic or white illumination.

### Advantageous Effects

In a case where the composition for an organic electroluminescent device according to the present invention is used for a hole injection layer, when carriers are recombined in a light emitting layer, excitons are formed by a band gap alignment due to a specific interfacial dipole formation, an improved density balance between holes and electrons, and a J/H-aggregate, and excitons are also formed by induction of intermolecular binding in a specific “β-lactam” structure of an antibiotic, induction of an aligned electric dipole, and a strong chromophore interaction, such that it is possible to remarkably improve the efficiency of the organic electroluminescent device.

Further, in a case where the composition for an organic electroluminescent device according to the present invention is used for a hole injection layer, it is possible to implement a low work function.

Further, the composition for an organic electroluminescent device according to the present invention is dispersed in water, such that acidity is adjusted in order to implement the efficiency of the organic electroluminescent device according to the object of the present invention, and the problem of rapidly shortening the lifespan of the device due to high acidity can be effectively suppressed.

Therefore, an organic electroluminescent device employs a hole injection layer material produced by using the composition for an organic electroluminescent device according to the present invention, such that it is possible to provide the organic electroluminescent device having an excellent light emitting property (efficiency) and lifespan.

### DESCRIPTION OF DRAWINGS

FIG. 1 shows a cross-sectional structure of an organic electroluminescent device according to the present invention.

FIG. 2 shows data indicating a performance of the organic electroluminescent device according to the present invention, that is, a light emitting amount/current density injection with respect to a driving voltage (Vₒₙ).

FIG. 3 shows data indicating a performance of the organic electroluminescent device according to the present invention, that is, a maximum current efficiency (CEₘₐₓ).

FIG. 4 shows data indicating a performance of the organic electroluminescent device according to the present invention, that is, a maximum external quantum efficiency (QEₘₐₓ).

FIG. 5 shows data indicating a performance of the organic electroluminescent device according to the present invention, that is, a maximum power efficiency (PEₘₐₓ).

### BEST MODE

Hereinafter, the present invention will be described in more detail. However, technical terms and scientific terms used herein have the general meaning understood by those skilled in the art to which the present invention pertains unless otherwise defined, and a description for the known function and configuration obscuring the present invention will be omitted in the following description.

The terms “alkyl”, “alkoxy”, and “thioxy” used herein and a substituent including alkyl refer to a functional group derived from a linear or branched hydrocarbon. In addition, alkyl and a substituent including alkyl according to the present invention preferentially have a short chain of 1 to 7 carbon atoms, and may be preferably selected from methyl, ethyl, propyl, and butyl, but are not limited thereto. In addition, the alkoxy refers to *—O-alkyl, and the thioxy refers to *—S-alkyl.

In addition, the term “alkenyl” used herein refers to an organic radical derived from a linear or branched hydrocarbon containing one or more double bonds, and “alkynyl” refers to an organic radical derived from a linear or branched hydrocarbon containing one or more triple bonds.

In addition, the term “carboxyl” used herein refers to *—COOH. In addition, the term “carboxylate” used herein refers to *—COOM, wherein M may be an alkali metal (Na, K, and the like).

In addition, the term “cycloalkyl” used herein refers to an organic radical derived from a completely saturated or partially unsaturated hydrocarbon ring having 3 to 9 carbon atoms, and “heterocycloalkyl” refers to an organic radical derived from a monocyclic or polycyclic non-aromatic ring containing 3 to 9 ring atoms containing one or more selected from B, N, O, S, Se, —P (═O)—, —C(═O)—, Si, and P.

In addition, the term “aryl” used herein refers to an organic radical derived from an aromatic hydrocarbon ring by removal of one hydrogen, includes a monocyclic or fused ring system containing suitably 4 to 7, preferably 5 or 6 ring atoms in each ring, and even includes a form in which a plurality of aryls are linked by a single bond. Examples thereof include phenyl, naphthyl, biphenyl, terphenyl, anthryl, indenyl, fluorenyl, phenanthryl, triphenylenyl, pyrenyl, perylenyl, chrysenyl, naphthacenyl, and fluoranthenyl, but are not limited thereto.

In addition, the term “heteroaryl” used herein refers to an organic radical derived from an aromatic ring by removal of one hydrogen, which may be an organic radical derived from a monocyclic or polycyclic aromatic ring containing 3 to 9 ring atoms containing one or more selected from B, N, O, S, Se, —P(═O)—, —C(═O)—, Si, and P, includes a monocyclic or fused ring system containing suitably 3 to 7, preferably 5 or 6 ring atoms in each ring, and even includes a form in which a plurality of heteroaryls are linked by a single bond. Examples thereof include monocyclic aromatic rings such as furyl, thiophenyl, pyrrolyl, pyranyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pirazinyl, pirimidinyl, and piridazinyl; and polycyclic aromatic rings such as benzofuranyl, benzothiophenyl, isobenzofuranyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinolizinyl, quinoxalinyl, carbazolyl, phenantridinyl, and benzodioxolyl, but are not limited thereto.

In addition, the term “halogen” used herein refers to a fluorine (F), chlorine (Cl), bromine (Br), or iodine (I) atom.

In addition, the term “lactam group” used herein refers to heterocycloalkyl containing an atomic group, which is —CONH—, in a ring, and the lactam group also includes an N-substituted lactam group.

In addition, the term “fused lactam group” used herein refers to the lactam group of which a ring forms a ring system fused with an aromatic ring or an alicyclic ring, and the alicyclic ring may be an organic radical derived from a completely saturated or partially unsaturated ring.

In addition, the term “compound of Formula 1” used herein may include an isomer thereof or an acceptable salt thereof. In this case, the acceptable salt refers to a salt according to an aspect of the present invention that may be used for general use or medical use and has a preferred activity of a compound. An example of the salt may include an alkali metal salt such as sodium salt or potassium salt, but is not limited thereto.

The present inventors recognized that it is possible to improve the efficiency of the organic electroluminescent device by a density balance between holes and electrons when carriers are recombined in a light emitting layer, and have studied a method for this. As a result, the present inventors found that it is possible to remarkably improve the efficiency of the organic electroluminescent device by adding a β-lactam-based compound containing both a primary amine and a secondary amine to a conductive polymer composite having an acidic group that is a main material of a hold injection layer, thereby completing the present invention.

The composition for an organic electroluminescent device according to the present invention may implement the formation of excitons by a band gap alignment due to a specific interfacial dipole formation, an improved density balance between holes and electrons, and a J/H-aggregate. Furthermore, an induction property of intermolecular binding in a “β-lactam” structure induces an aligned electric dipole. The aligned electric dipoles play a very important role in improving the efficiency of the organic electroluminescent device by generating J-aggregate energy and H-aggregate energy. Therefore, in a case where a material produced by using the composition for an organic electroluminescent device according to the present invention is used for a material for a hole injection layer, it is possible to provide an organic electroluminescent device that implements a maximum external quantum efficiency (QE) of 35.0%, a maximum current efficiency (CE) of 120.0 cd/A, and a maximum power efficiency (PE) of 68.0 lm/W.

Accordingly, herein, the present invention provides a new composition for a hole injection layer and a hole injection layer material produced by using the same that may improve the efficiency of the organic electroluminescent device so as to expand their applications.

In order to implement the above effect, the present invention provides a composition for an organic electroluminescent device, the composition containing: a conductive polymer composite having an acidic group; and a compound of the following Formula 1.

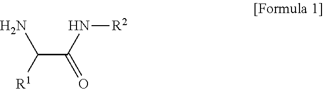

[In Formula 1,

R¹ is C₃-C₃₀cycloalkyl, C₃-C₃₀heterocycloalkyl, C₆-C₃₀aryl, or C₆-C₃₀heteroaryl;

R² is a lactam group or a fused lactam group;

the cycloalkyl, the heterocycloalkyl, the aryl, or the heteroaryl of R¹, and the lactam group or the fused lactam group of R² each independently may be further substituted with one or more substituents selected from halogen, hydroxy, cyano, carboxyl, carboxylate, C₁-C₃₀alkyl, C₁-C₃₀alkoxy, C₂-C₃₀alkenyl, C₂-C₃₀alkynyl, C₆-C₃₀aryl, and C₆-C₃₀heteroaryl; and

the heterocycloalkyl or the heteroaryl of R¹, and the lactam group or the fused lactam group of R² each independently include one or more selected from B, N, O, S, Se, —P(═O)—, —C(═O)—, Si, and P.]

The hole injection layer material produced by using the composition for an organic electroluminescent device according to an embodiment of the present invention causes a Fermi level alignment, such that both a strong attractive force with electrons and a weak hole injection are induced. That is, the hole injection layer material according to the present invention may effectively suppress the hole injection and remarkably improve a recombination efficiency due to the properties described above, such that the efficiency of the organic electroluminescent device may be remarkably improved.

According to the composition for an organic electroluminescent device according to an embodiment of the present invention, in the compound of Formula 1, R¹ may be C₃-C₃₀cycloalkyl or C₆-C₃₀aryl; and R² may be a lactam group fused with an alicyclic ring.

As an example, the lactam group fused with the alicyclic ring of R² may be a lactam group in which a ring system fused with C₁-C₂₀alkylene or C₂-C₂₀alkenylene is formed in a C₃-C₆heterocycloalkyl ring containing an atomic group, which is —CONH—, in the ring. In this case, one of the alkylene or —CH₂— of alkenylene may be substituted with a heteroatom such as —O— or —S—.

As an example, the lactam group fused with the alicyclic ring of R² may be a saturated or partially unsaturated ring.

According to the composition for an organic electroluminescent device according to an embodiment of the present invention, in the compound of Formula 1, R¹ may be C₃-C₃₀cycloalkyl or C₆-C₃₀aryl; and R² may be represented by the following Formula 2.

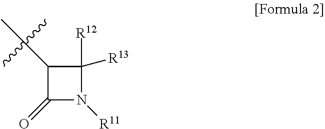

[In Formula 2,

R¹¹ is C₁-C₇alkyl or C₂-C₇alkenyl;

one of R¹² and R¹³ is hydrogen, C₁-C₇alkyl, C₁-C₇alkoxy, or C₁-C₇thioxy, and the other one may be connected to R¹¹ to form an alicyclic ring; and

the alkyl or the alkenyl of R¹¹ and the alicyclic ring formed by connecting one of R¹² and R¹³ to R¹¹ each independently may be further substituted with one or more substituents selected from halogen, hydroxy, cyano, carboxyl, carboxylate, C₁-C₇alkyl, C₁-C₇alkoxy, C₂-C₇alkenyl, C₂-C₇alkynyl, C₆-C₁₂aryl, and C₆-C₁₂heteroaryl, and —CH₂— in the alicyclic ring may be substituted with a heteroatom selected from O and S.]

As an example, in the compound of Formula 1, R¹ may be substituted or unsubstituted C₃-C₁₂cycloalkyl or substituted or unsubstituted C₆-C₁₂aryl; and R² may be represented by Formula 2.

As an example, in the compound of Formula 1, R¹ may be selected from cycloalkyl such as cyclopentyl, cyclohexyl, cycloheptyl, cyclooctyl, cyclopentadienyl, cyclohexadienyl, cycloheptadienyl, or cyclooctadienyl; and aryl such as phenyl, naphthyl, or biphenyl, the cycloalkyl or the aryl of R¹ may be further substituted with one or more substituents selected from halogen, hydroxy, cyano, carboxyl, and C₁-C₇alkyl, and R² may be represented by Formula 2.

In the composition for an organic electroluminescent device according to an embodiment of the present invention, specifically, the compound of Formula 1 may be at least one selected from a compound of the following Formula 3 and a compound of the following Formula 4.

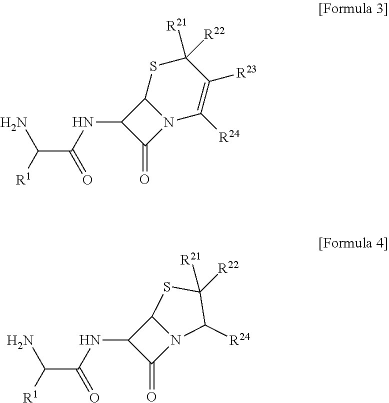

[In Formulas 3 and 4,

R¹ is C₃-C₁₂cycloalkyl or C₆-C₁₂aryl;

R²¹ to R²⁴ are each independently selected from hydrogen, halogen, hydroxy, cyano, carboxyl, carboxylate, and C₁-C₇alkyl; and

the cycloalkyl or the aryl of R¹ each independently may be further substituted with one or more substituents selected from halogen, hydroxy, cyano, carboxyl, and C₁-C₇alkyl.]

As an example, in the compound of Formula 3 or 4, R¹ may be selected from cycloalkyl such as cyclopentadienyl, cyclohexadienyl, cycloheptadienyl, or cyclooctadienyl; and aryl such as phenyl, naphthyl, or biphenyl, the cycloalkyl or the aryl of R¹ may be further substituted with one or more substituents selected from hydroxy and carboxyl, and R²¹ to R²⁴ each independently may be selected from hydrogen, halogen, hydroxy, cyano, carboxyl, carboxylate (*—COOM, wherein M is hydrogen, or an alkali metal such as K or Na), and alkyl such as methyl or ethyl.

In the composition for an organic electroluminescent device according to an embodiment of the present invention, more specifically, the compound of Formula 1 may be selected from the following structures.

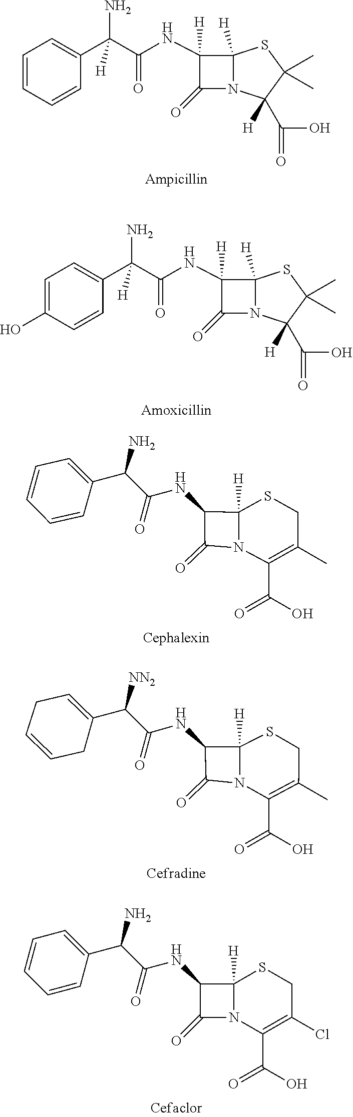

In addition, in the composition for an organic electroluminescent device according to an embodiment of the present invention, the compound of Formula 1 may be used by being diluted at an adequate concentration depending on a purpose.

As an example, the compound of Formula 1 may contain 0.01 to 0.5 wt % of the compound of Formula 1 and balance water.

As an example, the compound of Formula 1 may contain 1.0 to 10.0 wt % of the compound of Formula 1 and balance water.

In the composition for an organic electroluminescent device according to an embodiment of the present invention, the conductive polymer composite having an acidic group may contain sulfonate anions (*—SO₃⁻) and the like.

In the composition for an organic electroluminescent device according to an embodiment of the present invention, the conductive polymer composite having an acidic group may be a mixture of a polythiophene-based polymer and an aromatic sulfonate-based polymer.

Specifically, the conductive polymer composite having an acidic group may contain poly(styrenesulfonate), and more specifically, may be a mixture (PEDOT:PSS) of poly(3,4-ethlenedioxythiophene) and poly(styrenesulfonate).

As an example, the mixture (PEDOT:PSS) of poly(3,4-ethlenedioxythiophene) and poly(styrenesulfonate) may have a structure in which poly(3,4-ethlenedioxythiophene), which is a conductive polymer, is doped with poly(styrenesulfonate) as an acceptor.

As an example, the mixture (PEDOT:PSS) of poly(3,4-ethlenedioxythiophene) and poly(styrenesulfonate) may be present in a water-dispersed form as an ion composite. In this case, the PEDOT:PSS in a water-dispersed form may be contained at a solid content concentration of 1.3 to 1.7 wt % (balance water), the sulfonate anions may allow the PEDOT:PSS to have a pH of about 1 to less than 2, and thus the PEDOT:PSS may be acidic.

In the composition for an organic electroluminescent device according to an embodiment of the present invention, the compound of Formula 1 is added to the PEDOT:PSS in a water-dispersed form, such that a formation of excitons is effectively induced by a J/H-aggregate, whereby the efficiency of the organic electroluminescent device may be remarkably improved.

Specifically, according to the present invention, the efficiency of the organic electroluminescent device may be remarkably improved by adding a compound containing both a primary amine and a secondary amine to the mixture (PEDOT:PSS) of poly(3,4-ethlenedioxythiophene) and poly(styrenesulfonate), which is a main material for a hole injection layer. It should be noted that it was found that such effect is remarkable in the present invention as compared to that in the case where a compound containing a primary amine, a compound containing a secondary amine, or a mixture thereof is used.

In addition, according to the present invention, it is confirmed that it is possible to remarkably improve the efficiency of the organic electroluminescent device by employing one or more antibiotics selected from ampicillin, amoxicillin, cephalexin, cefradine, and cefaclor, as a compound satisfying the structural features described above, which shows a new use for the antibiotics described above.

The composition for an organic electroluminescent device according to an embodiment of the present invention may contain a primary amine group in the compound of Formula 1 in an amount of 10 moles or less, based on 1 mole of a sulfonic acid ion of the poly(styrenesulfonate). Specifically, the primary amine group in the compound of Formula 1 may be contained in an amount of 0.1 to 8 moles, and more specifically, 0.5 to 6 moles.

The composition for an organic electroluminescent device according to an embodiment of the present invention may contain the compound of Formula 1 in an amount of 0.1 to 80 vol % based on a total volume of the composition. Specifically, the composition may contain the compound of Formula 1 in an amount of 2 to 75 vol %, more preferably, 15 to 40 vol %, and still more preferably, 25 to 40 vol %. In this case, the residue of the composition may be the PEDOT:PSS in a water-dispersed form, and a solid content concentration thereof may be 1.3 to 1.7 wt %.

As an example, in a case where 25 ml of PEDOT:PSS (CLEVIOS P VP AL 4083, Heraeus, pH 1.48) in a water-dispersed form and 0.5 ml of ampicillin (Amp) are used, a total weight of the primary amine group may be 1.24 vg (2 vol % Amp-PEDOT:PSS, pH 2.10). In this case, the ampicillin (Amp) may be 5 wt % (balance water). The following examples may also be the same as described above.

As an example, in a case where 5 ml of PEDOT:PSS (CLEVIOS P VP AL 4083, Heraeus, pH 1.48) in a water-dispersed form and 0.5 ml of ampicillin are used, a total weight of the primary amine group may be 1.24 vg (10 vol % Amp-PEDOT:PSS, pH 2.80).

As an example, in a case where 2.5 ml of PEDOT:PSS (CLEVIOS P VP AL 4083, Heraeus, pH 1.48) in a water-dispersed form and 0.5 ml of ampicillin are used, a total weight of the primary amine group may be 1.24 vg (15 vol % Amp-PEDOT:PSS, pH 3.20).

As an example, in a case where 3 ml of PEDOT:PSS (CLEVIOS P VP AL 4083, Heraeus, pH 1.48) in a water-dispersed form and 1 ml of ampicillin are used, a total weight of the primary amine group may be 2.48 vg (25 vol % Amp-PEDOT:PSS, pH 4.48).

As an example, in a case where 3 ml of PEDOT:PSS (CLEVIOS P VP AL 4083, Heraeus, pH 1.48) in a water-dispersed form and 2 ml of ampicillin are used, a total weight of the primary amine group may be 4.95 vg (40 vol % Amp-PEDOT:PSS, pH 7.36).

As an example, in a case where 1 ml of PEDOT:PSS (CLEVIOS P VP AL 4083, Heraeus, pH 1.48) in a water-dispersed form and 3 ml of ampicillin are used, a total weight of the primary amine group may be 7.43 vg (75 vol % Amp-PEDOT:PSS, pH 8.28).

The pH is measured with a pH meter (SX723, Portable pH/Conductivity Meter, Range: (pH:−2.00 to 19.99 pH), Resolution: pH: 0.1/0.01/0.001 pH, Accuracy: pH:±0.01, Shanghai San-Xin Instrument, China), and the measurement of pH is not limited as long as a glass electrode that is commonly used in an acidity measurement by those skilled in the art is used.

In a case where the compound of Formula 1 is used under the conditions described above, a pH of the composition for an organic electroluminescent device is 9.0 or less, and thus a desired effect in the present invention is stably implemented.

Specifically, in the compound of Formula 1, since the lactam group is unstable in a condition in which a pH exceeds 7.5, a ring opening is performed, and thus it is difficult to induce a formation of excitons by a J/H-aggregate due to the structure change. Alternatively, excitons may be formed by a strong chromophore interaction, and thus it is possible to expect efficiency improvement. However, it is difficult to achieve this effect under a condition in which a pH exceeds 9.0.

In the composition for an organic electroluminescent device according to an embodiment of the present invention, a pH of the composition may be specifically 2.0 to 8.5, and more specifically, 3.0 to 7.5.

A hole injection layer material produced by using the composition for an organic electroluminescent device that satisfies the pH condition described above may simultaneously implement a formation of excitons by an improved density balance between holes and electrons and a J/H-aggregate, and a formation of excitons by a strong chromophore interaction. Furthermore, an induction property of intermolecular binding in a specific “β-lactam” structure of an antibiotic induces an aligned electric dipole. The aligned electric dipoles play a very important role in improving the efficiency of the organic electroluminescent device by generating J- and H-aggregate energy. Accordingly, the organic electroluminescent device containing the hole injection layer material according to the present invention has an excellent efficiency (current efficiency, external quantum efficiency, power efficiency, and the like) as compared to that of an organic electroluminescent device according to the related art.

In addition, the composition of an organic electroluminescent device that satisfies the pH condition has a lower work function. Therefore, a hole injection is suppressed, such that an electron/hole recombination can be effectively performed.

The present invention provides a hole injection layer material produced by using the composition for an organic electroluminescent device, the composition containing a conductive polymer composite having an acidic group; and a compound of Formula 1, and an organic electroluminescent device employing the same.

The hole injection layer material according to an embodiment of the present invention has a low work function, and implements a further improved efficiency by a formation of excitons by a J/H-aggregate and a strong chromophore interaction.

In addition, by employing the hole injection layer material according to an embodiment of the present invention, the problem of rapidly shortening the lifespan of the device due to high acidity may be effectively suppressed.

Hereinafter, the organic electroluminescent device according to an embodiment of the present invention will be described, but the present invention is not limited by a structure thereof.

The organic electroluminescent device according to an embodiment of the present invention includes an anode, a hole injection layer containing the hole injection layer material, a hole transport layer, a light emitting layer, an electron transport layer, and a cathode.

In addition, the organic electroluminescent device may further include an electron injection layer between the light emitting layer and the cathode.

In addition, the organic electroluminescent device may further include an electron blocking layer between the hole transport layer and the light emitting layer, and a hole blocking layer between the light emitting layer and the electron transport layer.

In addition, the organic electroluminescent device may be deposited by an environmentally friendly solution process using an organic solvent such as a halogenated solvent or a halogen-free solvent as well as a vacuum deposition manner.

Hereinafter, a method of manufacturing the organic electroluminescent device according to the present invention will be described.

On a substrate formed of glass or plastic, an anode may be formed by using a material such as a conductive polymer such as a mixed metal oxide such as indium-tin oxide (ITO), fluorine doped tin oxide (FTO), ZnO-Ga₂O₃, ZnO-Al₂O₃, or SnO₂-Sb₂O₃, polyaniline, or polythiophene. According to a preferred embodiment, ITO is used for forming the anode.

As a material effective in injecting electrons, which are negative-charge carriers, a material for a cathode may be selected from gold, aluminum, copper, or silver, and alloys thereof; aluminum, indium, calcium, barium, or magnesium, and alloys thereof, such as a calcium/aluminum alloy, a magnesium/silver alloy or an aluminum/lithium alloy; and a metal such as a rare earth element, lanthanide, or actinide in some cases, and the material for a cathode is preferably aluminum, or an aluminum/calcium alloy.

The hole injection layer is formed by using the composition for an organic electroluminescent device according to the present invention. That is, the hole injection layer formed by using the composition for an organic electroluminescent device according to the present invention has a low work function, and simultaneously implements a formation of excitons by an improved density balance between holes and electrons and a J/H-aggregate, and a formation of excitons by induction of intermolecular binding in a specific “β-lactam” structure of an antibiotic, induction of an aligned electric dipole, and a strong chromophore interaction, such that the organic electroluminescent device has a remarkably improved efficiency. In particular, the organic electroluminescent device has a remarkably improved efficiency at a low driving voltage.

In addition, by employing the hole injection layer according to the present invention, the hole injection layer may serve to effectively improve interface properties with the anode material such as ITO, and to make an uneven surface of the ITO smooth by being coated on an upper portion of the ITO. In particular, in order to suppress the hole injection according to the present invention, the hole injection layer may adequately adjust a difference between a work function level of ITO, which may be used as an anode, and a HOMO level of the hole transport layer.

In this case, a common material may be further used for the hole injection layer, and examples thereof may include aromatic amines such as copper phthlalocyanine (CuPc), N,N′ -dinaphthyl-N,N′-phenyl-(1,1′-biphenyl)-4,4′-diamine (NPD), 4,4′,4″-tris [methylphenyl(phenyl)amino] triphenyl amine (m-MTDATA), 4,4′,4″-tris [1-naphthyl (phenyl)amino] triphenyl amine (1-TNATA), 4,4′,4″-tris[2-naphthyl(phenyl)amino] triphenyl amine (2-TNATA), and 1,3,5-tris[N-(4-diphenylaminophenyl)phenylamino] benzene (p-DPA-TDAB), but are not limited thereto. In this case, specifically, the hole injection layer may be coated on an upper portion of the anode at a thickness of 10 to 100 nm.

In order to smoothly transport holes, a material having a HOMO level higher than that of the light emitting layer may be used for the hole transport layer. Examples of the material for the hole transport layer may include a low molecular material such as tris(4-carbazoyl -9-ylphenyl)amine (TCTA), 4,4′-cyclohexylidenebis [N,N-bis(4-methylphenyl) benzenamine] (TAPC), N,N′-bis(3-methylphenyl)-N,N′-diphenyl- [1,1′-diphenyl]-4,4′-diamine (TPD), N,N′-bis(1-naphthyl)-N,N′-biphenyl-[1,1′-biphenyl]-4,4′-diamine (TPB), N,N′-di(naphthalene-1-yl)-N,N′-diphenyl-benzidene (NPB), triphenylamine (TPA), bis[4-(N,N-diethylamino) -2-methylphenyl[(4-methylphenyl) methane (MPMP), N,N,N′,N′-tetrakis(4-methylphenyl) -(1,1′-biphenyl)-4,4-diamine (TTB), or N,N′-bis(4-methylphenyl)-N,N′-bis(4-ethylphenyl) -[1,1′-(3,3′-dimethyl)biphenyl]-4,4′-diamine (ETPD); and a high molecular material such as polyvinylcarbazole, polyaniline, or (phenylmetyl)polysilane, but are not limited thereto.

The light emitting layer may include a fluorescent or phosphorescent material, as a material that emits red (R), green (G), and blue (B). Preferably, the light emitting layer may be a green light emitting layer. The green light emitting layer may be one of a yellowish red light emitting layer, a yellowish green light emitting layer, and a dark green light emitting layer. In a case where the light emitting layer is a green light emitting layer, a wavelength range of light emitted therefrom may be in a range of 490 nm to 580 nm.

In addition, the light emitting layer includes a dopant compound and a host compound, and a known material that emits light as described above may be used for the light emitting layer. An example of the dopant compound may be a metal complex containing one or more metals selected from Jr, Ru, Pd, Pt, Os, and Re. In addition, examples of a ligand forming the metal complex may include a 2-phenylpyridine derivative, a 7,8-benzoquinoline derivative, a 2-(2-thienyl)pyridine derivative, a 2-(1-naphthyl)pyridine derivative, and a 2-phenylquinoline derivative, and the ligand may further have an additional substituent. Specific examples of the dopant compound may include bisthienylpyridine acetylacetonate iridium, bis(benzothienylpyridine)acetylacetonate iridium, bis(2-phenylbenzothiazole)acetylacetonate iridium, bis(1-phenylisoquinoline) iridium acetylacetonate, tris(1-phenylisoquinoline)iridium, tris(phenylpyridine)iridium, tris(2-biphenylpyridine)iridium, tris(3-biphenylpyridine)iridium, and tris(4-biphenylpyridine)iridium, but are not limited thereto.

Specific examples of the host compound may include 9,9-dimethyl-10-phenyl-2-(3-(1,4,5-triphenyl-1H-imidazol-2-yl)phenyl)-9,10-dihydroacridine (PAmTPI), diphenyl-4-triphenylsilylphenylphosphine oxide (TSPO1), 4,4-N,N-dicarbazole-biphenyl (CBP), N,N-dicarbazoyl -3,5-benzene (mCP), poly(vinylcarbazole) (PVK), polyfluorene, 4,4′-bis[9-(3 ,6biphenylcarbazolyl)]-1-1,1′-biphenyl4,4′-bis[9-(3,6-biphenylcarbazolyl)]-1-1,1′-biphenyl, 9,10-bis[(2′,7′-t-butyl)-9′,9″-spirobifluorenylanthracene, tetrafluorene, 9-(4-(9H-pyrido[2,3-b[indol-9-yl)phenyl)-9H-3,9′-bicarbazole (pBCb2Cz), and 9-(3-(9H-carbazole-9-yl)phenyl)-3-(dibromophenylphosphoryl) -9H-carbazole (mCPPO1), but are not limited thereto. In this case, specifically, the light emitting layer may be coated at a thickness of 5 to 200 nm.

The electron transport layer is mainly formed of a material containing a chemical component attracting electrons. To this end, it is required for the electron transport layer to have a high electron mobility, and the electron transport layer stably supplies electrons to the light emitting layer by a smooth electron transport. Examples of the material for the electron transport layer may include diphenyl-4-triphenylsilylphenylphosphine oxide (TSPO1), 1,3,5-tris(N-phenylbenzimiazole-2-yl) benzene (TPBi); tris(8-hydroxyquinolinato)aluminum (Alq₃); 2,9-dimethyl-4,7-diphenyl-1,10-phenanthroline (DDPA); an azole compound such as 2-(4-biphenyl) -5-(4-tert-butyl)-1,3,4-oxadizole (PBD) or 3-(4-biphenyl)-4-phenyl-5-(4-tert-butyl)-1,2,4-triazole (TAZ); phenylquinozaline; and 3,3′-[5′-[3-(3-pyridinyl)phenyl][1,1′:3′,1″-terphenyl]-3,3″-diyl[bispyridine (TmPyPB), but are not limited thereto. In this case, according to a preferred embodiment, TPBi is used and may be coated on an upper portion of the light emitting layer at a thickness of 5 to 100 nm.

The electron injection layer is for smoothly inducing electron injection. Unlike other charge transfer layers, an alkali metal ion such as LiF, BaF₂, CsF, or Liq or an alkaline rare earth metal ion is used for the electron injection layer, and the electron injection layer may be configured to induce doping on the electron transport layer by cations of these metals.

In addition, the organic electroluminescent device may further include an electron blocking layer between the hole transport layer and the light emitting layer, and a hole blocking layer between the light emitting layer and the electron transport layer, and a known electron blocking material and a hole blocking material may be used for the electron blocking layer and the hole blocking layer.

The organic electroluminescent device according to the present invention may be used in a display device, or a device for monochromatic or white illumination.

Hereinafter, the present invention will be described in more detail with reference to Examples.

Terms and words used in the present specification and claims are not to be construed as a general or dictionary meaning but are to be construed as meaning and concepts meeting the technical ideas of the present invention based on a principle that the inventors can appropriately define the concepts of terms in order to describe their own inventions in best mode. Therefore, configurations described in exemplary embodiments and the accompanying drawings of the present invention do not represent all of the technical spirits of the present invention, but are merely most preferable embodiments. Therefore, it should be understood that there may be various equivalents and modified examples that could substitute therefore at the time of filing the present application.

### EXAMPLE 1

An indium tin oxide (ITO) glass substrate was used for an anode. The ITO glass substrate is obtained by being washed with deionized water, acetone, and isopropanol at an ultrasonic wave of 40 kHz, removing residual organic matters present on a surface thereof, and being subjected to a surface ultraviolet ray-ozone (UVO) treatment in order to increase a work function.

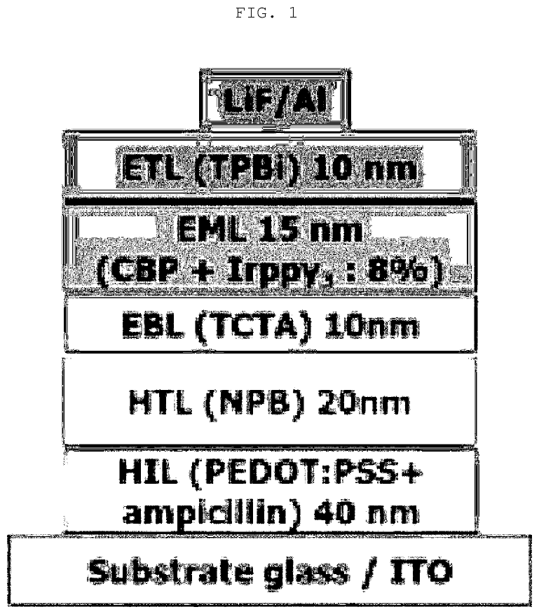

On an upper portion of the ITO glass substrate, a hole injection layer (40 nm) formed of a 2vol % Amp-PEDOT:PSS (2 vol % ampicillin and residual PEDOT:PSS; PEDOT:PSS: CLEVIOS P VP AL 4083, Heraeus, pH 2.10) was formed, and a hole transport layer (20 nm) formed of N,N-bis-(1-naphthyl)-N,N′-diphenyl-1,1′-biphenyl-4,4′-diamine (NPB); a hole transport layer (10 nm) formed of tris(4-carbazoyl-9-ylphenyl)amine (TCTA); a light emitting layer (15 nm) obtained by adjusting a deposition rate of Ir(ppy)₃ which is a dopant with respect to a deposition rate (1.0 Å/s) of 4,4-N,N-dicarbazole-biphenyl (CBP) which is a host to 0.8 Å/s; an electron transport layer (10 nm) formed of 1,3,5-tris(N-phenylbenzimidazol-2-yl)benzene (TPBi); and a cathode formed of LiF/A1 (1 nm/120 nm) were sequentially stacked by thermal evaporation, thereby obtaining a green phosphorescent organic electroluminescent device having a cross-sectional structure as shown in FIG. 1.

Light emitting properties of the green phosphorescent organic electroluminescent device were evaluated. A light emitting area was 4 mm², and a forward bias voltage as a direct voltage was used as a driving voltage.

### EXAMPLE 2

A green phosphorescent organic electroluminescent device having the same cross-sectional structure as in Example 1 was obtained by using 10 vol % Amp-PEDOT:PSS (pH 2.80) instead of the 2 vol % Amp-PEDOT:PSS (2 vol % ampicillin and residual PEDOT:PSS; PEDOT:PSS: CLEVIOS P VP AL 4083, Heraeus) in Example 1, and light emitting properties thereof were evaluated in the same method as that of Example 1.

### EXAMPLE 3

A green phosphorescent organic electroluminescent device having the same cross-sectional structure as in Example 1 was obtained by using 15 vol % Amp-PEDOT:PSS (pH 3.20) instead of the 2 vol % Amp-PEDOT:PSS (2 vol % ampicillin and residual PEDOT:PSS; PEDOT:PSS: CLEVIOS P VP AL 4083, Heraeus) in Example 1, and light emitting properties thereof were evaluated in the same method as that of Example 1.

### EXAMPLE 4

A green phosphorescent organic electroluminescent device having the same cross-sectional structure as in Example 1 was obtained by using 25 vol % Amp-PEDOT:PSS (pH 4.48) instead of the 2 vol % Amp-PEDOT:PSS (2 vol % ampicillin and residual PEDOT:PSS; PEDOT:PSS: CLEVIOS P VP AL 4083, Heraeus) in Example 1, and light emitting properties thereof were evaluated in the same method as that of Example 1.

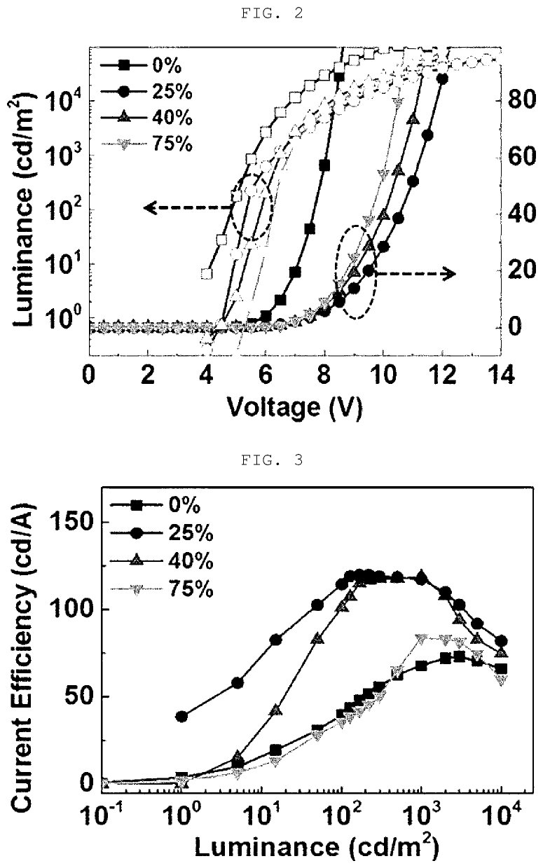

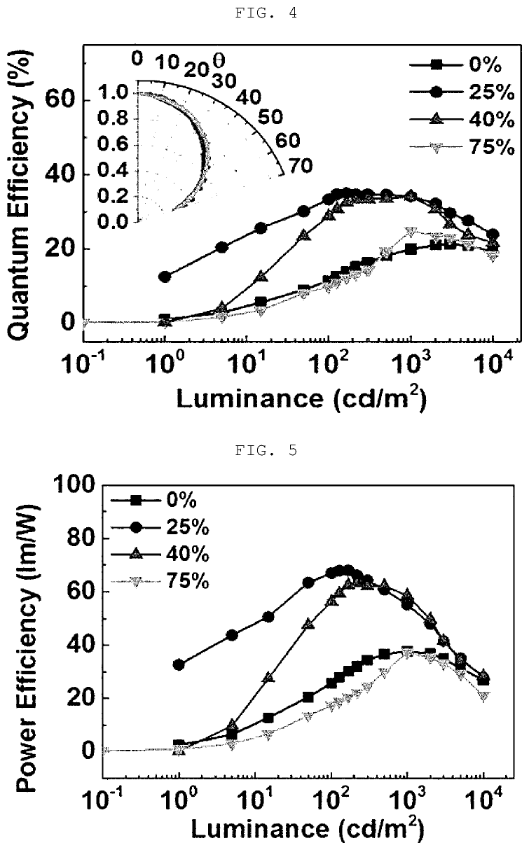

As a result, the green phosphorescent organic electroluminescent device showed a maximum external quantum efficiency (EQE) of 35.0%, a maximum current efficiency of 120.0 cd/A, and a maximum power efficiency of 68.0 Im/W or more (see Table 1 and FIGS. 2 to 5).

### EXAMPLE 5

A green phosphorescent organic electroluminescent device having the same cross-sectional structure as in Example 1 was obtained by using 40 vol % Amp-PEDOT:PSS (pH 7.36) instead of the 2 vol % Amp-PEDOT:PSS (2 vol % ampicillin and residual PEDOT:PSS; PEDOT:PSS: CLEVIOS P VP AL 4083, Heraeus) in Example 1, and light emitting properties thereof were evaluated in the same method as that of Example 1.

As a result, the green phosphorescent organic electroluminescent device showed a maximum external quantum efficiency (QE) of 34.1%, a maximum current efficiency (CE) of 118.9 cd/A, and a maximum power efficiency (PE) of 63.3 Im/W (see Table 1 and FIGS. 2 to 5).

### EXAMPLE 6

A green phosphorescent organic electroluminescent device having the same cross-sectional structure as in Example 1 was obtained by using 75 vol % Amp-PEDOT:PSS (pH 8.28) instead of the 2 vol % Amp-PEDOT:PSS (2 vol % ampicillin and residual PEDOT:PSS; PEDOT:PSS: CLEVIOS P VP AL 4083, Heraeus) in Example 1, and light emitting properties thereof were evaluated in the same method as that of Example 1.

As a result, the green phosphorescent organic electroluminescent device showed a maximum external quantum efficiency of 24.9%, a maximum current efficiency of 83.7 cd/A, and a maximum power efficiency of 37.7 Im/W (see Table 1 and FIGS. 2 to 5).

### Comparative Example 1

A green phosphorescent organic electroluminescent device having the same cross-sectional structure as in Example 1 was obtained by using only PEDOT:PSS (0 vol % Amp-PEDOT :PSS, pH 1.48) instead of the ampicillin in Example 1, and light emitting properties thereof were evaluated in the same method as that of Example 1.

As a result, the green phosphorescent organic electroluminescent device showed a maximum external quantum efficiency of 21.3%, a maximum current efficiency of 72.9 cd/A, and a maximum power efficiency of 37.7 Im/W (see Table 1 and FIGS. 2 to 5).

A performance of the organic electroluminescent device according to the present invention, that is, a driving voltage (Vₒₙ), a maximum external quantum efficiency (QE), a maximum current efficiency (CE), a maximum power efficiency (PE), and a color coordinate (CIE) were measured. The results thereof are shown in Table 1 and FIGS. 2 to 5.

Specifically, the performance of the organic electroluminescent device depending on a voltage change was measured. The measurement was performed using a current voltage meter (Keithley 2400A Source Meter) and a luminance meter (Minolta CS-2000) while increasing a voltage at a constant interval (0.5 V) from −5 V to 15 V. The external quantum efficiency, the current efficiency, and the power efficiency were calculated by using the measured driving voltage, current density, luminance, and color coordinate value. The measured results are shown in FIGS. 2 to 5, and the maximum values of the respective efficiency results are shown in Table 1.

TABLE 1

| | | Number of moles of | | | | | |
|---|---|---|---|---|---|---|---|
| | Light emitting | primary amines, based | | | | | |
| Example | layer (EML) | on 1 mole of PSS | Vₒₙ^{a)} [V] | EQEₘₐₓ [%] | CEₘₐₓ [cd/A] | PEₘₐₓ [lm/W] | CIE (x, y) |
| 4 | 25 vol % Amp- | 0.556 | 4.5 | 35.0 | 120.0 | 68.0 | (0.286, 0.633) |
| | PEDOT:PSS | | | | | | |
| | (pH 4.48) | | | | | | |
| 5 | 40 vol % Amp- | 1.113 | 4.5 | 34.1 | 118.9 | 63.3 | (0.303, 0.620) |
| | PEDOT:PSS | | | | | | |
| | (pH 7.36) | | | | | | |
| 6 | 75 vol % Amp- | 5.006 | 6.5 | 24.9 | 83.7 | 37.7 | (0.309, 0.620) |
| | PEDOT:PSS | | | | | | |
| | (pH 8.28) | | | | | | |
| Comparative | 0 vol % Amp- | 0.0 | 3.5 | 21.3 | 72.9 | 37.7 | (0.286, 0.628) |
| Example 1 | PEDOT:PSS | | | | | | |
| | (pH 1.48) | | | | | | |

*Calculating of number of moles of primary amines, based on 1 mole of PSS = (mol concentration of amp) × (amp vol %)/(mol concentration of PEDOT:PSS) × (100-amp vol %)
mol concentration of amp.
$\begin{matrix}\frac{50 mg}{1 ml} \times \frac{1 mol}{371.39 g} \times \frac{1 g}{1000 mg} = 1.35 \times {10}^{- 4} mol \text{/} ml \\ ( Amp concentration ) \times ( 1 \text{/} amp vol weight ) \times ( unit conversion )\end{matrix}$ mol concentration of PSS
$\begin{matrix}\frac{0.017 g ( PEDOT \text{:} PSS )}{1 g ( Solution )} ( \% ) \frac{1 mol ( PSS )}{( \frac{140.2 g}{mol} ) \times 0.218 mol + ( \frac{183.2 g}{mol} ) \times 1 mol} \frac{1.017 g}{1 ml} = 8.09 \times {10}^{- 5} mol \text{/} ml \\ ( weight of solid content 1.7 \% ) \times ( PSS mol ratio \text{/} PEDOT \text{:} PSS weight with mol ratio ) \times ( approximation solution density )\end{matrix}$

As shown in Table 1, it was confirmed that the organic electroluminescent device employing the hole injection layer produced by using the composition for an organic electroluminescent device according to the present invention may implement a high color purity with the improved efficiency even at a low driving voltage.

In addition, the organic electroluminescent device according to the present invention shows an excellent power efficiency, a high color purity due to emission of light with a high luminance even at a low driving voltage, and an excellent quantum efficiency, as compared to those in Comparative Example 1. Therefore, the organic electroluminescent device according to the present invention may significantly reduce power consumption, and thus may implement an excellent power efficiency.

In addition, the organic electroluminescent device according to the present invention may effectively suppress the problem of rapidly shortening the lifespan of the device due to high acidity of the hole injection layer material.

Specifically, the organic electroluminescent device according to the present invention implements a maximum external quantum efficiency of 35.0%, a maximum current efficiency of 120.0 cd/A, and a maximum power efficiency of 68.0 m/W. Such performances of the organic electroluminescent device according to the present invention are higher than those of any single unit green phosphorescent organic electroluminescent device reported so far, and it is expected that the organic electroluminescent device according to the present invention is effectively used in a high performance display device, or device for monochromatic or white illumination.

In addition, the organic electroluminescent device according to the present invention follows a Lambertian curve. It was proved that the measured value is not fictional through integrating sphere measurement. Therefore, it is expected that the organic electroluminescent device according to the present invention is practically applied to the current organic electroluminescent device technical field to improve the efficiency of the organic electroluminescent device.

The present invention has been described in detail with reference to examples as set forth above, but those skilled in the art to which the invention pertains can implement various modifications without departing from the spirit and scope of the present invention defined in appended claims. Therefore, alterations of the examples of the present invention would not depart from the technique of the present invention.

1. A composition for an organic electroluminescent device, the composition comprising:
a conductive polymer composite having an acidic group; and
a compound of the following Formula 1, 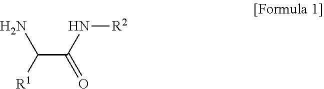
[in Formula 1,
R¹ is C₃-C₃₀cycloalkyl, C₃-C₃₀heterocycloalkyl, C₆-C₃₀aryl, or C₆-C₃₀heteroaryl;
R² is a lactam group or a fused lactam group;
the cycloalkyl, the heterocycloalkyl, the aryl, or the heteroaryl of R¹, and the lactam group or the fused lactam group of R² each independently may be further substituted with one or more substituents selected from halogen, hydroxy, cyano, carboxyl, carboxylate, C₁-C₃₀alkyl, C₁-C30alkoxy, C₂-C₃₀alkenyl, C₂-C₃₀alkynyl, C₆-C₃₀aryl, and C₆-C₃₀heteroaryl; and
the heterocycloalkyl or the heteroaryl of R¹, and the lactam group or the fused lactam group of R² each independently include one or more selected from B, N, O, S, Se, —P(═O)—, —C(═O)—, Si, and P].

2. The composition of claim 1, wherein in the compound, R¹ is C₃-C₃₀cycloalkyl or C₆-C₃₀aryl; and R² is a lactam group fused with an alicyclic ring.

3. The composition of claim 1, wherein in the compound, R² is represented by the following Formula 2, 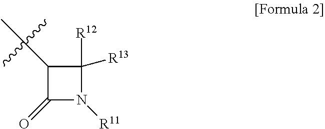
[in Formula 2,
R¹¹ is C₁-C₇alkyl or C₂-C₇alkenyl;
one of R¹² and R¹³ is hydrogen, C₁-C₇alkyl, C₁-C₇alkoxy, or C₁-C₇thioxy, and the other one may be connected to R¹¹ to form an alicyclic ring; and
the alkyl or the alkenyl of R¹¹ and the alicyclic ring formed by connecting one of R¹² and R¹³ to R¹¹ each independently may be further substituted with one or more substituents selected from halogen, hydroxy, cyano, carboxyl, carboxylate, C₁-C₇alkyl, C₁-C₇alkoxy, C₇alkenyl, C₂-C₇alkynyl, C₆-C₁₂aryl, and C₆-C₁₂heteroaryl, and —CH₂— in the alicyclic ring may be substituted with a heteroatom selected from O and S].

4. The composition of claim 1, wherein the compound is at least one selected from a compound of the following Formula 3 and a compound of the following Formula 4, 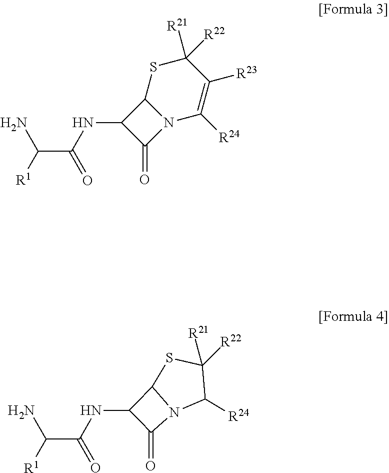
[in Formulas 3 and 4,
R¹ is C₃-C₁₂cycloalkyl or C₆-C₁₂aryl;
R²¹ to R²⁴ are each independently selected from hydrogen, halogen, hydroxy, cyano, carboxyl, carboxylate, and C₁-C₇alkyl; and
the cycloalkyl or the aryl of R¹ each independently may be further substituted with one or more substituents selected from halogen, hydroxy, cyano, carboxyl, and C₁-C₇alkyl].

5. The composition of claim 1, wherein the compound is selected from ampicillin, amoxicillin, cephalexin, cefradine, and cefaclor.

6. The composition of claim 1, wherein the conductive polymer composite having an acidic group is a mixture of a polythiophene-based polymer and an aromatic sulfonate-based polymer.

7. The composition of claim 6, wherein the conductive polymer composite having an acidic group is a mixture of poly(3,4-ethlenedioxythiophene) and poly(styrenesulfonate).

8. The composition of claim 1, wherein a pH of the composition is 9.0 or less.

9. The composition of claim 1, wherein a pH of the composition is 2.0 to 8.5.

10. The composition of claim 7, wherein the composition contains a primary amine group in the compound of Formula 1 in an amount of 10 moles or less, based on 1 mole of a sulfonic acid ion of the poly(styrenesulfonate).

11. A hole injection layer material produced by using the composition of claim 1.

12. An organic electroluminescent device containing the hole injection layer material of claim 11.

13. The organic electroluminescent device of claim 12, comprising an anode, a hole injection layer containing the hole injection layer material, a hole transport layer, a light emitting layer, an electron transport layer, and a cathode.

14. The organic electroluminescent device of claim 12, wherein the organic electroluminescent device is a display device, or a device for monochromatic or white illumination.
